(19) United States
(12) Patent Application Publication
(10) Pub. No.: US 2024/0312767 A1
(43) Pub. Date: Sep. 19, 2024

(54) Plasma Processing Apparatus

(71) Applicant: Tokyo Electron Limited, Tokyo (JP)

(72) Inventors: Taro HAYAKAWA, Yamanashi (JP); Taro Ikeda, Yamanashi (JP); Eiki Kamata, Yamanashi (JP)

(21) Appl. No.: 18/592,336

(22) Filed: Feb. 29, 2024

(30) Foreign Application Priority Data
Mar. 13, 2023 (JP) 2023-038575

(51) Int. Cl. H01J 37/32

(52) U.S. Cl. CPC H01J 37/3222; H01J 37/32229; H01J 2237/327

(57) ABSTRACT

A plasma processing apparatus comprises a processing chamber having an upper opening, a dielectric ceiling plate that is disposed to close the opening and partitions an inner space and an outer space of the processing chamber, and a plurality of electromagnetic wave supplies disposed on the dielectric ceiling plate and configured to supply electromagnetic waves into the processing chamber. The dielectric ceiling plate has a cavity between the plurality of electromagnetic wave supplies. The cavity is formed in a surface of the dielectric ceiling plate in contact with the outer space or formed inside the dielectric ceiling plate.

### CROSS-REFERENCE TO RELATED APPLICATIONS

This application claims priority to Japanese Patent Application No. 2023-038575 filed on Mar. 13, 2023, the entire contents of which are incorporated herein by reference.

### TECHNICAL FIELD

The present disclosure relates to a plasma processing apparatus.

### BACKGROUND

For example, Japanese Laid-open Patent Publication No. 2012-216745 suggests a microwave introducing device that generates plasma from a processing gas using microwaves introduced into a processing chamber and performs plasma processing on a substrate. A conductive member constituting a ceiling wall is disposed at the ceiling of the processing chamber. The conductive member has a plurality of openings, a plurality of dielectric windows are fitted into the plurality of openings. The microwaves are introduced into the processing chamber from the dielectric windows.

### SUMMARY

The present disclosure provides a technique capable of suppressing interference between a plurality of electromagnetic wave supplies for supplying electromagnetic waves into a plasma processing apparatus.

In accordance with one embodiment of the present disclosure, a plasma processing apparatus comprises a processing chamber having an upper opening, a dielectric ceiling plate that is disposed to close the opening and partitions an inner space and an outer space of the processing chamber, and a plurality of electromagnetic wave supplies disposed on the dielectric ceiling plate and configured to supply electromagnetic waves into the processing chamber, wherein the dielectric ceiling plate has a cavity between the plurality of electromagnetic wave supplies, and the cavity is formed in a surface of the dielectric ceiling plate in contact with the outer space or formed inside the dielectric ceiling plate.

### BRIEF DESCRIPTION OF THE DRAWINGS

FIG. 1 is a schematic cross-sectional view showing an example of a plasma processing apparatus according to an embodiment.

FIGS. 2A to 2C show examples of arrangement of cavities and slot antennas of a dielectric ceiling plate according to an embodiment.

FIG. 3 explains the effect of the cavities of the dielectric ceiling plate according to the embodiment.

FIGS. 4A and 4B show examples of the cross section of the cavities of the dielectric ceiling plate according to the embodiment.

FIGS. 5A and 5B explain simulation on the presence or absence of cavities of the dielectric ceiling plate and the interference between slot antennas according to the embodiment.

FIG. 6 shows an example of the arrangement area of the cavities of the dielectric ceiling plate according to the embodiment.

FIGS. 7A to 7E show examples of the gap between the cavities of the dielectric ceiling plate according to the embodiment and simulation results.

FIGS. 8A to 8C show others example of the cavities of the dielectric ceiling plate according to the embodiment.

FIGS. 9A and 9B show examples of arrangement of the cavities disposed under slots of the slot antenna according to the embodiment.

### DETAILED DESCRIPTION

Hereinafter, embodiments of the present disclosure will be described with reference to the accompanying drawings. Like reference numerals will be given to like parts throughout the drawings, and redundant description thereof may be omitted.

### <Plasma Processing Apparatus>

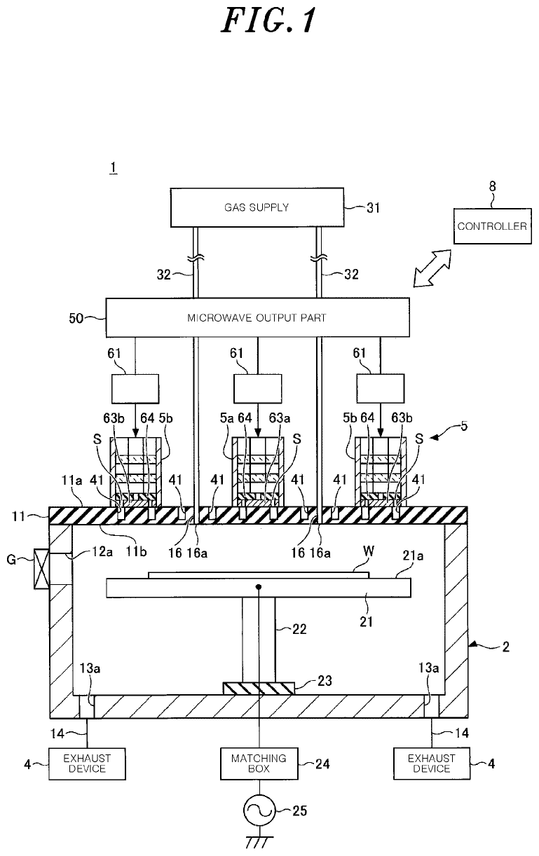

The configuration of a plasma processing apparatus according to an embodiment will be described with reference to FIG. 1. FIG. 1 is a schematic cross-sectional view showing an example of a plasma processing apparatus according to an embodiment. A plasma processing apparatus 1 includes a processing chamber 2 accommodating a substrate W, e.g., a semiconductor wafer, and a dielectric ceiling plate 11. The processing chamber 2 has a substantially cylindrical shape, for example, and has an upper opening. The processing chamber 2 is made of a metal such as aluminum or an alloy thereof. The dielectric ceiling plate 11 is disposed to close the upper opening of the processing chamber 2, and partitions the inner space and the outer space of the processing chamber 2. The inner space of the processing chamber 2 partitioned by the dielectric ceiling plate 11 is a vacuum side, and the outer space thereof is an atmosphere side. The dielectric ceiling plate 11 is made of a dielectric such as alumina (Al₂O₃) or the like. The surface of the dielectric ceiling plate 11 in contact with the outer space is covered with a metal (not shown).

Further, the plasma processing apparatus 1 includes a gas supply 31 for supplying a processing gas into the processing chamber 2, an exhaust device 4 for exhausting the processing chamber 2, and an electromagnetic wave supply 5 for introducing microwaves as an example of electromagnetic waves into the processing chamber 2.

A plurality of electromagnetic wave supplies 5 are disposed on the dielectric ceiling plate 11. The electromagnetic wave supplies 5 include an inner supply 5a and outer supplies 5b arranged at the outer side of the inner supply 5a. The dielectric ceiling plate 11 has cavities 41 between the plurality of electromagnetic wave supplies 5. The cavities 41 may be formed in the surface of the dielectric ceiling plate 11 in contact with the outer space, or may be formed inside the dielectric ceiling plate 11. For example, as shown in FIG. 1, the cavities 41 are formed in the surface of the dielectric ceiling plate 11 in contact with the outer space between the inner supply 5a and the outer supplies 5b.

A microwave output part 50 has a distributor (not shown). The microwaves are distributed by the distributor and introduced into the inner supply 5a and the outer supplies 5b via a microwave introducing module 61. The inner supply 5a has a slot antenna 63a directly above the dielectric ceiling plate 11. Similarly, the outer supplies 5b has slot antennas 63b directly above the dielectric ceiling plate 11. Slots S are formed in the slot antennas 63a and 63b.

The inner supply 5a has a coaxial waveguide structure serving as a microwave transmission path, and supplies microwaves into the processing chamber 2 through the slot S of the slot antenna 63a. Similarly, the outer supplies 5b have a coaxial waveguide structure serving as a microwave transmission path, and supply microwaves into the processing chamber 2 through the slots S of the slot antenna 63b. The slot antennas 63a and 63b are made of a metal. Wave retardation plates 64 formed of dielectric plates are disposed directly above the slot antennas 63a and 63b.

A placing table 21 is disposed in the processing chamber 2. The placing table 21 has a placing surface 21a, and the substrate W is placed on the placing surface 21a. The placing table 21 is supported by a support member 22 and insulated by an insulating member 23 disposed between the support member 22 and the processing chamber 2.

A plurality of (two in FIG. 1) exhaust ports 13a are formed at the bottom portion of the processing chamber 2. The exhaust device 4 is connected to the exhaust port 13a through an exhaust line 14. The exhaust device 4 reduces a pressure in the processing chamber 2 to a desired pressure (vacuum). A transfer port 12a for transferring the substrate W or the like is formed in the sidewall of the processing chamber 2, and is opened and closed by a gate valve G.

A radio frequency (RF) bias power supply 25 is connected to the placing table 21 via a matching box 24. The RF bias power supply 25 supplies an RF power to the placing table 21 to attract ions to the substrate W.

The gas supply 31 is connected to a plurality of gas nozzles 16 through a plurality of gas supply lines 32. The gas nozzles 16 penetrate through the dielectric ceiling plate 11, and have gas holes 16a at the tip ends thereof. The processing gas supplied from the gas supply 31 passes through the gas supply lines 32 and the plurality of gas nozzles 16, and is supplied into the processing chamber 2 from the gas holes 16a.

A controller 8 processes computer-executable instructions for executing various operations of the plasma processing apparatus 1 described in the present disclosure. In one embodiment, the controller 8 may be partially or entirely included in the plasma processing apparatus 1. In one embodiment, the controller 8 may be separate from the plasma processing apparatus 1 and connected to the plasma processing apparatus 1 to be communicable therewith. The controller 8 may include a processing part, a storage part, and a communication interface.

The controller 8 is realized by, e.g., a computer. The processing part may be configured to read a program from the storage part and perform various control operations by executing the read program. Such a program may be stored in the storage part in advance, or may be acquired via a medium when necessary. The acquired program is stored in the storage part, and is read from the storage part and executed by the processing part. The medium may be various computer-readable storage media, or may be a communications line connected to the communications interface. The processing part may be a central processing unit (CPU). The storage part may include a random access memory (RAM), a read only memory (ROM), a hard disk drive (HDD), a solid state drive (SSD), or a combination thereof. The communication interface may communicate with the plasma processing apparatus 1 through a communication line such as a local area network (LAN) or the like.

### <Dielectric Ceiling Plate>

A conductive member may be disposed, instead of the dielectric ceiling plate 11, at the ceiling wall of a conventional plasma processing apparatus. The conductive member has a plurality of openings, and a dielectric window is fitted into each opening. Microwaves are introduced into the processing chamber from the dielectric windows.

In such a configuration, plasma is locally generated under the dielectric windows. In order to uniformly supply plasma onto the substrate, it is necessary to increase the distance (gap) between the dielectric windows and the placing table 21 so that plasma can diffuse in the space therebetween. Accordingly, the distance (gap) increases to a certain extent, which hinders scaling down of the device. Further, in such a configuration, a gap may be generated between the conductive member and the dielectric windows, and particles may be generated.

In contrast, in the plasma processing apparatus 1 of the present embodiment, a single dielectric ceiling plate 11 constitutes the ceiling wall of the processing chamber 2. Accordingly, generation of particles can be prevented.

Further, microwaves can be supplied into the processing chamber 2 from the entire surface of the single dielectric ceiling plate 11. Hence, even if the distance (gap) is reduced, plasma can be uniformly supplied onto the substrate, and the device can be scaled down.

On the other hand, in the plasma processing apparatus 1 of the present embodiment, the plurality of electromagnetic wave supplies 5 are used to adjust the distribution of plasma density. In this case, it is necessary to match the impedances in all the electromagnetic wave supplies 5.

When the plurality of electromagnetic wave supplies 5 are placed on the single dielectric ceiling plate 11, interference between the electromagnetic wave supplies 5 occurs. In this specification, “interference” refers to phenomenon that the impedance matching is disturbed by electromagnetic waves entering the electromagnetic wave supplies 5. When the interference occurs, the microwaves outputted from one electromagnetic wave supply 5 may enter another electromagnetic wave supply 5, so that the impedance matching may not be performed. In this case, it is not possible to efficiently input a microwave power into other electromagnetic wave supplies 5.

### <Cavity>

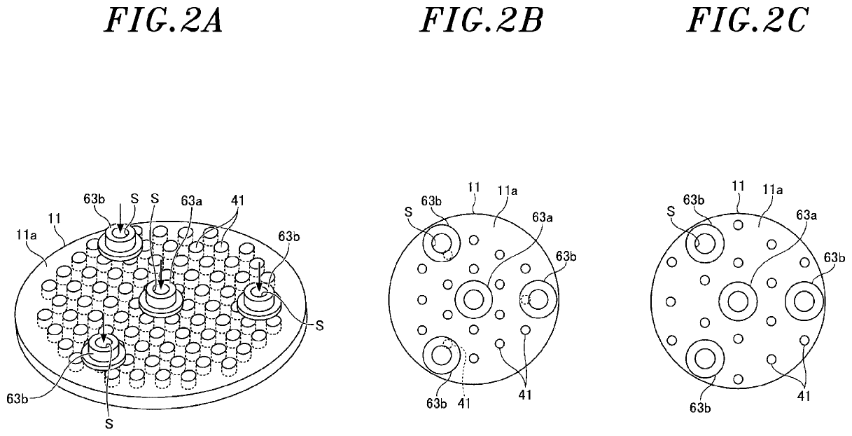

Therefore, the cavities 41 are provided in the surface of the dielectric ceiling plate 11. FIGS. 2A to 2C show examples of the arrangement of the cavities 41 of the dielectric ceiling plate 11, and the slot antenna 63a of the inner supply 5a and the slot antennas 63b of the outer supplies 5b according to the embodiment. The surface of the dielectric ceiling plate 11 where the cavities 41 are provided is a surface 11a in contact with the outer space (atmospheric side) between the slot antenna 63a of the inner supply 5a and the slot antennas 63b of the outer supplies 5b shown in FIGS. 2A to 2C. Further, as shown in FIG. 1, the surface 11a is the opposite surface of the surface 11b of the dielectric ceiling plate 11 that is in contact with the inner space of the processing chamber 2. The interval (pitch) between adjacent cavities 41 is narrowest in FIG. 2A, and becomes wider in the order of FIG. 2B and FIG. 2C. In the examples of FIGS. 2A to 2C, the cavities 41 are arranged at equal intervals. The cavities 41 are disposed between the slot antenna 63a and the slot antenna 63b as long as the cavities 41 are disposed inside a circle passing through the outermost edges of the plurality of outer supplies 5b. The recesses of the cavities 41 may be unevenly arranged. As shown in FIG. 2, the cavities 41 are not necessarily arranged at positions that are symmetrical with respect to the center of the dielectric ceiling plate 11.

If the cavities 41 are formed in the dielectric ceiling plate 11, when the microwaves propagate through the dielectric ceiling plate 11, scattering of the microwaves occurs in the cavities 41. Accordingly, the interference between the plurality of electromagnetic wave supplies 5 for supplying microwaves can be suppressed. In the examples of FIGS. 2A to 2C, one inner supply 5a (the slot antenna 63a) is disposed at the upper central portion of the dielectric ceiling plate 11. Further, at the upper portion of the dielectric ceiling plate 11, three outer supplies 5b (the slot antennas 63b) are disposed on the outer peripheral side of the inner supply 5a. However, the number and arrangement of the electromagnetic wave supplies 5 are not limited thereto.

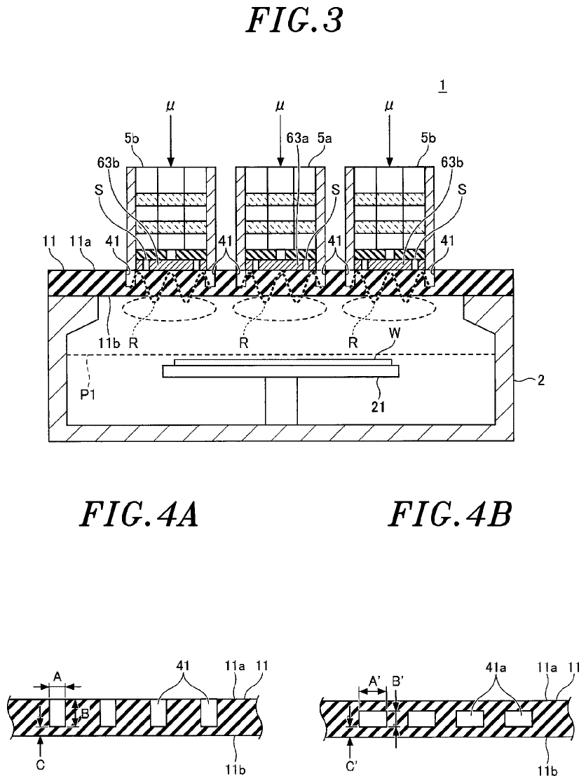

FIG. 3 explains the effect of the cavities 41 of the dielectric ceiling plate 11 according to the embodiment. Microwaves R supplied from the inner supply 5a and the outer supplies 5b and transmitted through the dielectric ceiling plate 11 cause scattering in the cavities 41. The scattering also includes refraction or reflection of microwaves. Accordingly, the ratio of microwaves emitted from one electromagnetic wave supply 5 and incident on other electromagnetic wave supplies 5 can be reduced, and the interference between the electromagnetic wave supplies 5 can be suppressed. As a result, the microwave power can be efficiently inputted into each of the electromagnetic wave supplies 5. Since the microwaves are supplied into the processing chamber 2 from the entire single dielectric ceiling plate 11, plasma P1 can be uniformly supplied to the substrate W even if the distance (gap) between the dielectric ceiling plate 11 and the placing table 21 is small.

For example, the dielectric ceiling plate 11 is alumina (Al₂O₃) having a relative dielectric constant of 10, and the cavity 41 is air having a relative dielectric constant of 1. The microwaves in the dielectric ceiling plate 11 are reflected when they enter the cavities 41 having a low relative dielectric constant from alumina having a high relative dielectric constant, and are totally reflected when they enter the cavities 41 at a certain angle or less. Accordingly, the microwaves are unlikely to reach the area partitioned by the cavities 41 having different relative dielectric constants. Hence, the interference between the electromagnetic wave supplies 5 can be suppressed by dividing the dielectric ceiling plate 11 disposed between the electromagnetic wave supplies 5 by the cavities 41 having different relative dielectric constants. Further, when the cavities 41 are cylindrical recesses, the circumferential intensity distribution of microwaves generated at the outer circumferential edges of the recesses can be equalized.

FIGS. 4A and 4B schematically show cross sections of some of the cavities 41 of the dielectric ceiling plate 11 according to the embodiment. The cavities 41 are cylindrical recesses formed in the surface 11a (upper surface) of the dielectric ceiling plate 11 in contact with the outer space of the processing chamber 2.

A diameter A of the recess of the cavity 41 shown in FIG. 4A may be λ/(24√εᵣ) to λ/(4√εᵣ). When A is the wavelength of electromagnetic waves (microwaves) in the cavity 41, λ₀ is the wavelength of the electromagnetic waves (microwaves) in vacuum, and εᵣ is the relative dielectric constant of the cavity 41, the equation λ=λ₀/√εᵣ is satisfied.

Further, a depth B of the recess of the cavity 41 is greater than or equal to ½ of the thickness of the dielectric ceiling plate 11, and a thickness C from the surface 11b of the dielectric ceiling plate 11 in contact with the inner space of the processing chamber 2 to the bottom portion of the recess is 1 mm or more to prevent damages to the dielectric ceiling plate 11. The diameter A, the depth B, and the thickness C may be the same or may be different in all the cavities 41.

In this manner, the recesses of the cavities 41 may be recessed in the dielectric ceiling plate 11 such that the upper portion of the dielectric ceiling plate 11 is opened, and may be covered with a dielectric. The depth B of the recess is not limited to λ/4, and may vary. On the other hand, in the plasma processing apparatus 1 including a conductive member, instead of the dielectric ceiling plate 11, disposed at the ceiling wall of the processing chamber 2, a recess having a depth of λ/4 is disposed in the bottom surface of the conductive member. Accordingly, the microwaves propagating through the conductive member become weak in the recess, and the microwaves are prevented from propagating beyond the recess. However, the recess formed in the dielectric ceiling plate 11 of the present embodiment has a configuration and a function different from those of a choke in the plasma processing apparatus 1 including a conductive member.

As shown in FIG. 4B, the dielectric ceiling plate 11 may have the cavities 41a therein. In this case, the cavities 41a have a cylindrical shape, and are not opened to the surfaces 11a and 11 b of the dielectric ceiling plate 11. Also in this case, a diameter A′ of the cavity 41a may be λ/(24 εᵣ) to λ/(4 εᵣ). Further, a depth B′ of the cavity 41a is greater than or equal to ½ of the thickness of the dielectric ceiling plate 11, and a thickness C′ from the surface 11b of the dielectric ceiling plate 11 in contact with the inner space of the processing chamber 2 to the bottom portion of the recess is 1 mm or more to prevent damages to the dielectric ceiling plate 11. The diameter A′, the depth B′, and the thickness C′ may be the same or may be different in all the cavities 41a.

As shown in FIGS. 4A and 4B, the cavities 41 and 41a are not formed in the surface 11b (the bottom surface) of the dielectric ceiling plate 11 in contact with the inner space of the processing chamber 2. In other words, the surface 11b of the dielectric ceiling plate 11 is a flat surface. If the cavities 41 and 41a are formed in the surface 11b of the dielectric ceiling plate 11, plasma is generated mainly in the cavities 41, and has different densities near the surface 11b of the dielectric ceiling plate 11. Further, particles may be generated by forming the cavities 41 and 41a in the bottom surface of the dielectric ceiling plate 11. Thus, the surface 11b of the dielectric ceiling plate 11 is formed flat. Accordingly, the plasma density can become uniform, and the generation of particles can be prevented.

### <Simulation Result>

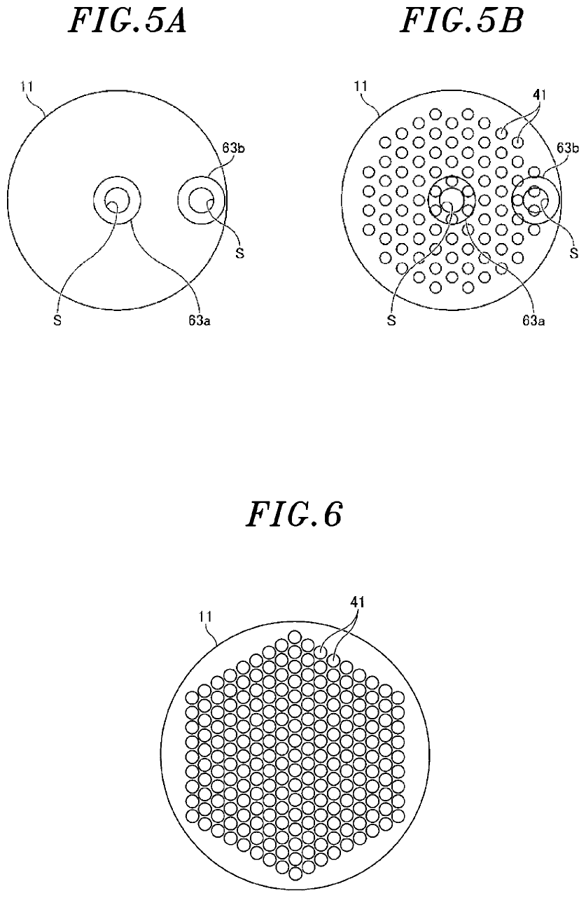

The effect of providing the recesses of the cavities 41 in the dielectric ceiling plate 11 will be described with reference to FIGS. 5A to 5B based on the electromagnetic field simulation results. FIGS. 5A and 5B explain the simulation on the presence or absence of the cavities 41 of the dielectric ceiling plate 11 according to the embodiment and the interference between the slot antennas 63a and 63b.

In FIG. 5A, the ratio of microwaves outputted from the inner slot antenna 63a and incident on the outer slot antenna 63b in the case of using the dielectric ceiling plate 11 having no cavity 41, that is, the absolute value of the input value/the output value is calculated by simulation.

In FIG. 5B, the ratio of microwaves outputted from the inner slot antenna 63a and incident on the outer slot antenna 63b in the case of using the dielectric ceiling plate 11 in which the recesses of the cavities 41 are formed at predetermined intervals (pitches) is calculated by simulation.

As a result, in the case of using the dielectric ceiling plate 11 having no recess of the cavity 41 shown in FIG. 5A, the ratio of microwaves outputted from the inner slot antenna 63a and incident on the outer slot antenna 63b was about 0.0647.

On the other hand, in the case of using the dielectric ceiling plate 11 having the recesses of the cavities 41 shown in FIG. 5B, the ratio of microwaves outputted from the inner slot antenna 63a and incident on the outer slot antenna 63b was about 0.0256. In other words, by providing the recesses of the cavities 41 in the dielectric ceiling plate 11 between the inner slot antenna 63a and the outer slot antenna 63b, the microwave power incident on the slot antenna 63b from the slot antenna 63a can be reduced to ⅓. In other words, the recesses of the cavities 41 can suppress the interference between the slot antennas 63a and 63b.

### <Cavity Arrangement Area>

The arrangement area of the cavities 41 will be described with reference to FIG. 6. FIG. 6 shows a case the cavities 41 are arranged in a hexagonal lattice area. In the example of FIG. 6, the outermost cavities 41 are arranged to form a substantially hexagonal shape. However, the arrangement area of the cavities 41 is not limited to a hexagonal lattice area, and may be a square lattice area. When the arrangement area of the cavity 41 is a square lattice area, the outermost cavities 41 are arranged to form a substantially square shape.

### <Interval Between Cavities>

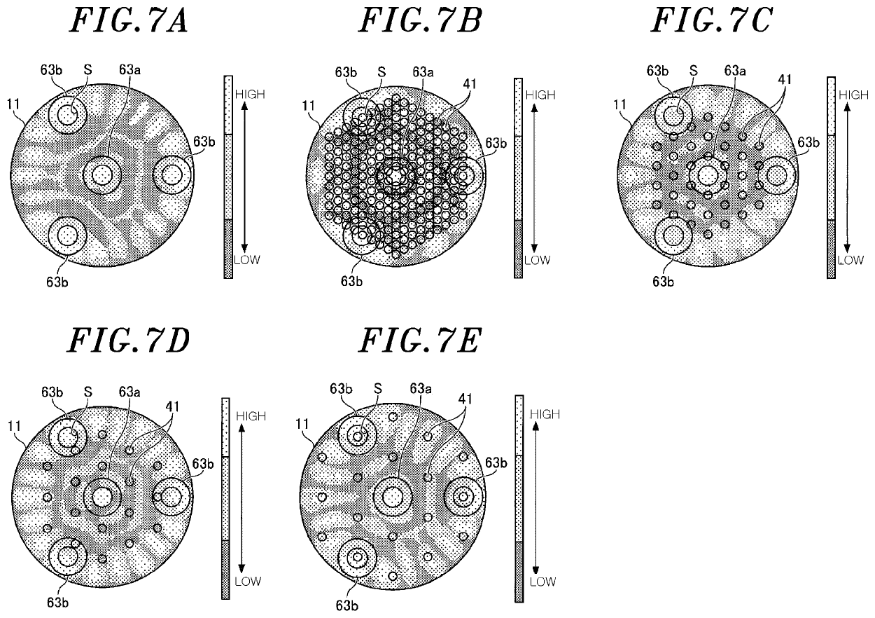

The interval (pitch) of the cavities 41 will be described with reference to FIGS. 7A to 7E. FIGS. 7A to 7E show examples of the interval between the cavities 41 of the dielectric ceiling plate 11 according to the embodiment. FIG. 7A shows the case of using the dielectric ceiling plate 11 having no recess of the cavity 41 and shows the simulation result of the electric field intensity distribution on the dielectric ceiling plate 11 in the case of supplying microwaves from the slot antennas 63a and 63b of one inner supply 5a and three outer supplies 5b. FIGS. 7B to 7E show the case of using the dielectric ceiling plate 11 having the recesses of the cavities 41 and shows the simulation results of the electric field intensity distribution on the dielectric ceiling plate 11 in the case of supplying microwaves from the slot antennas 63a and 63b while changing the interval between the cavities 41. The interval between the cavities 41 is the distance between the outer edges of the recesses of adjacent cavities 41. In this simulation, the diameter of the recess of the cavity 41 is set to 20 mm, and the depth thereof is set to 18 mm.

The interval between the cavities 41 shown in FIG. 7B is smallest (25 mm), and gradually increases in the order of FIGS. 7C, 7D, and 7E. The interval between the cavities 41 shown in FIG. 7E is largest (100 mm).

The electric field intensity distribution on any of the dielectric ceiling plates 11 in FIGS. 7B to 7E is different from that on the dielectric ceiling plate 11 having no cavity 41 in FIG. 7A. Further, it is clear from the simulation result that the interval (25 mm to 100 mm) between the cavities 41 has the effect of suppressing the propagation of microwaves.

The interval between the cavities 41 is preferably set such that the microwaves cannot pass the gap between adjacent recesses. When the interval is λ/2 or less, it is difficult for the microwaves to pass the gap between adjacent recesses. Therefore, the distance between the outer edges of the recesses of adjacent cavities 41 may be λ/2 or less. Accordingly, the interference between the electromagnetic wave supplies 5 can be suppressed by suppressing the propagation of microwaves, and the circumferential electric field intensity distribution of microwaves generated at the outer edges of the cylindrical recesses can be equalized.

### <Other Examples of Cavity>

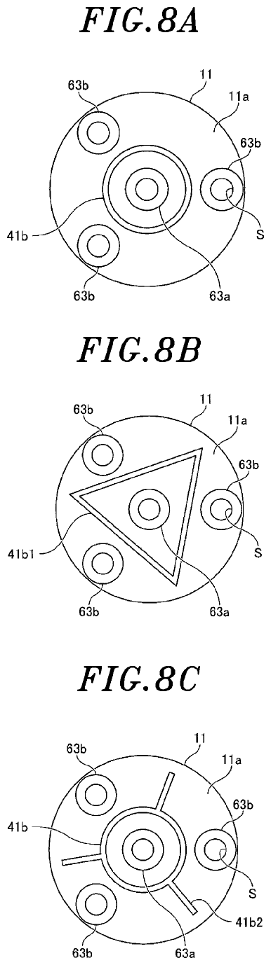

Examples of other shapes of the cavity will be described with reference to FIGS. 8A to 8C. FIGS. 8A to 8C show other examples of the cavities of the dielectric ceiling plate 11 according to the embodiment. In FIG. 8A, a cavity 41b that is a ring-shaped groove is formed between the slot antenna 63a of the inner supply 5a and the slot antenna 63b of the outer supply 5b. The cavity 41b is formed in the surface 11a of the dielectric ceiling plate 11 in contact with the outer space (the atmosphere side).

The number of the ring-shaped groove of the cavity 41b is not limited to one, and a plurality of ring-shaped grooves may be disposed concentrically. The microwaves supplied from the inner supply 5a and the outer supplies 5b and transmitted through the dielectric ceiling plate 11 cause scattering in the ring-shaped groove between the inner supply 5a and the outer supply 5b. Hence, the interference between the electromagnetic wave supplies 5 can be suppressed.

As a result, the microwave power can be efficiently supplied to each electromagnetic wave supply 5. When a plurality of ring-shaped grooves are disposed, the grooves are not necessarily spaced apart from each other at equal intervals.

The groove of the cavity 41b does not necessarily have a ring shape, and may have an arc shape, a linear shape, a star shape, or a combination of one or more of these shapes.

For example, in FIG. 8B, a cavity 41b1 formed by connecting linear grooves is disposed between the slot antenna 63a of the inner supply 5a and the slot antennas 63b of the outer supplies 5b. In the example of FIG. 8B, the cavity 41b1 is formed in an approximately triangular shape having three vertices that are the joints of the grooves. When the number of the outer supply portions 5b is n, the groove is formed in a substantially n-gonal shape having an n-number of apices.

In FIG. 8C, a cavity 41b2 formed by linear grooves arranged in a star shape is disposed between the slot antennas 63b of the three outer supplies 5b. Further, a cavity 41b formed by a ring-shaped groove is disposed between the slot antenna 63a of the inner supply 5a and the slot antennas 63b of the three outer supplies 5b.

The cavity 41b formed by the ring-shaped groove and the cavity 41b2 formed by three linear grooves are connected.

The grooves of the above-described cavities 41b, 41b1, and 41b2 has a width of 1 mm or more. Accordingly, the microwaves transmitted through the dielectric ceiling plate 11 cause scattering in the grooves, and the interference between the electromagnetic wave supplies 5 can be suppressed.

The depths of the grooves of the cavities 41b, 41b1, and 41b2 are greater than or equal to ½ of the thickness of the dielectric ceiling plate 11, and the length from the surface 11b (the bottom surface) of the dielectric ceiling plate 11 in contact with the inner space of the processing chamber 2 to the bottom portion of the groove is 1 mm or more to prevent damages to the dielectric ceiling plate.

### <Cavity Below Slot>

In the dielectric ceiling plate 11, the cavities 41 may be disposed under the slots S of the slot antennas 63a and 63b to overlap at least partially therewith in plan view.

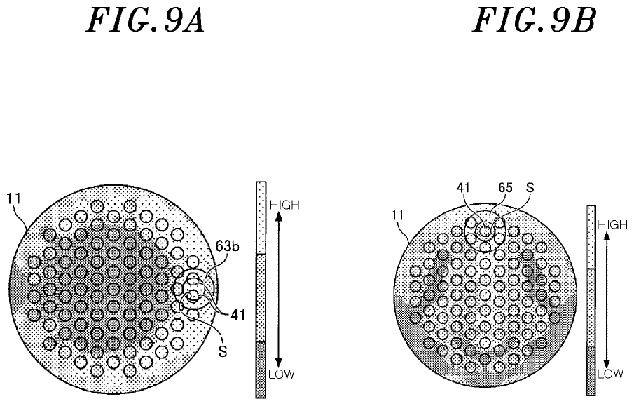

A case where the recesses of the cavities 41 at least partially overlap with the slots S of the slot antennas 63a and 63b will be described with reference to FIGS. 9A and 9B. FIGS. 9A and 9B show examples in which the cavities 41 are disposed under the slots S of the slot antennas according to the embodiment.

In FIG. 9A, two cavities 41 are arranged in a vertical direction under the slot S of the slot antenna 63b. In this case, in the example of FIG. 9A, the regions where the electric field intensity is strong are arranged in the vertical direction under the slot S.

On the other hand, in the example of FIG. 9B, the cavity 41 is disposed under the center of the slot S of the slot antenna 63b. In this case, the regions where the electric field intensity is strong are arranged in a vertical direction and a horizontal direction under the slot S. Accordingly, the electric field intensity distribution on the dielectric ceiling plate 11 can become uniform or can be adjusted, and plasma can be uniformly generated. The cavities 41 disposed directly below the slots S of the slot antennas 63a and 63b are not limited to cylindrical recesses, and may be grooves.

### <Other Applications>

Although the slot antennas 63a and 63b have been described in FIG. 1, the present disclosure is not limited thereto, and a monopole antenna may be used instead of the slot antennas 63a and 63b.

The cavities 41, 41a, 41b, 41b1, and 41b2 may be filled with a dielectric material having a relative dielectric constant lower than that of the dielectric ceiling plate 11. When microwaves enter a medium having a high dielectric constant from a medium having a low dielectric constant, total reflection occurs at a certain angle or more. In this case, the microwaves incident on the medium having a low dielectric constant repeat total reflection and return to the medium having a high dielectric constant in random orientation, so that the microwaves can be scattered. Therefore, by forming the cavities 41 having a relative dielectric constant lower than that of the dielectric ceiling plate 11 at the dielectric ceiling plate 11, the microwaves scatter at the boundary between the cavities 41 and the dielectric ceiling plate 11, and the ratio of electromagnetic waves outputted from one electromagnetic wave supply 5 and incident on other electromagnetic wave supplies 5 can be reduced.

When a conductor is embedded in the cavities 41, 41a, 41b, 41b1, and 41b2, the conductor is heated by microwaves and the microwave loss occurs. Therefore, the cavities 41, 41a, 41b, 41b1, and 41b2 are preferably filled with a dielectric material.

The cavities 41, 41a, 41b, 41b1, and 41b2 do not penetrate through the dielectric ceiling plate 11 in the thickness direction. This is because the dielectric ceiling plate 11 partitions the atmosphere side from the inner space (the vacuum side) of the processing chamber.

As described above, in accordance with the plasma processing apparatus of the present embodiment, the regions having different relative dielectric constants on the dielectric ceiling plate 11 are provided, so that the scattering of the electromagnetic waves (microwaves) occur, and the ratio of electromagnetic waves outputted from one electromagnetic wave supply 5 and incident on other electromagnetic wave supplies 5 can be reduced. Accordingly, the interference between the plurality of electromagnetic wave supplies 5 for supplying electromagnetic waves into the plasma processing apparatus can be suppressed.

1. A plasma processing apparatus comprising:
a processing chamber having an upper opening;
a dielectric ceiling plate that is disposed to close the opening and partitions an inner space and an outer space of the processing chamber; and
a plurality of electromagnetic wave supplies disposed on the dielectric ceiling plate and configured to supply electromagnetic waves into the processing chamber,
wherein the dielectric ceiling plate has a cavity between the plurality of electromagnetic wave supplies, and
the cavity is formed in a surface of the dielectric ceiling plate in contact with the outer space or formed inside the dielectric ceiling plate.

2. The plasma processing apparatus of claim 1, wherein the plurality of electromagnetic wave supplies have an inner supply and an outer supply disposed at an outer side of the inner supply, and
the cavity is formed between the inner supply and the outer supply.

3. The plasma processing apparatus of claim 1, wherein the cavity is a groove formed in the surface of the dielectric ceiling plate in contact with the outer space.

4. The plasma processing apparatus of claim 2, wherein the cavity is a groove formed in the surface of the dielectric ceiling plate in contact with the outer space.

5. The plasma processing apparatus of claim 3, wherein the groove has a ring shape, an arc shape, a linear shape, or a star shape.

6. The plasma processing apparatus of claim 3, wherein a width of the groove is 1 mm or more.

7. The plasma processing apparatus of claim 3, wherein a depth of the groove is greater than or equal to ½ of the thickness of the dielectric ceiling plate, and
a length from a surface of the dielectric ceiling plate in contact with the inner space to a bottom portion of the groove is 1 mm or more to prevent damage to the dielectric ceiling plate.

8. The plasma processing apparatus of claim 1, wherein the cavity is a cylindrical recess formed in the surface of the dielectric ceiling plate in contact with the outer space.

9. The plasma processing apparatus of claim 2, wherein the cavity is a cylindrical recess formed in the surface of the dielectric ceiling plate in contact with the outer space.

10. The plasma processing apparatus of claim 8, wherein a diameter of the recess is λ/(24 εᵣ) to λ/(4 εᵣ), and
when λ is a wavelength of electromagnetic waves in the cavity, λ₀ is a wavelength of electromagnetic waves in vacuum, and εᵣ is a relative dielectric constant of the cavity, an equation λ=λ₀/√εᵣ is satisfied.

11. The plasma processing apparatus of claim 8, wherein a plurality of the cylindrical recesses are provided, and
a distance between outer edges of adjacent recesses is λ/2 or less.

12. The plasma processing apparatus of claim 8, wherein a depth of the recess is greater than or equal to ½ of a thickness of the dielectric ceiling plate, and
a length from the surface of the dielectric ceiling plate in contact with the inner space to a bottom portion of the recess is 1 mm or more to prevent damage to the dielectric ceiling plate.

13. The plasma processing apparatus of claim 8, wherein the cavity is filled with a dielectric material having a relative dielectric constant lower than a relative dielectric constant of the dielectric ceiling plate.

14. A plasma processing apparatus comprising:
a processing chamber having an upper opening;
a dielectric ceiling plate that is disposed to close the opening and partitions an inner space and an outer space of the processing chamber; and
a plurality of electromagnetic wave supplies disposed on the dielectric ceiling plate, each having a slot antenna, and configured to supply electromagnetic waves into the processing chamber through a slot of the slot antenna;
wherein the dielectric ceiling plate has a cavity disposed under the slot of the slot antenna to at least partially overlap with the slot in plan view, and
the cavity is formed in a surface of the dielectric ceiling plate in contact with the outer space or formed inside the dielectric ceiling plate.

15. The plasma processing apparatus of claim 14, wherein the cavity is a cylindrical recess formed in the surface of the dielectric ceiling plate in contact with the outer space.
